(19) United States
(12) Patent Application Publication
(10) Pub. No.: US 2019/0253590 A1
(43) Pub. Date: Aug. 15, 2019

(54) Camera Module

(71) Applicant: AAC Technologies Pte. Ltd., Singapore city (SG)

(72) Inventor: Chuandong Wei, Shenzhen (CN)

(21) Appl. No.: 16/236,309

(22) Filed: Dec. 28, 2018

(30) Foreign Application Priority Data
Feb. 9, 2018 (CN) 201820256515.1

(51) Int. Cl. H04N 5/225; H05K 1/18

(52) U.S. Cl. CPC H04N 5/2257; H04N 5/2253; H05K 2201/10151; H05K 1/183; H04N 5/2254

(57) ABSTRACT

The present application discloses a camera module, including: a circuit board; a sensor electrically connected to the circuit board; a substrate mounted on the circuit board and including a receiving area for receiving the sensor; a number of lenses; and a mounting board for carrying the lenses. The mounting board includes a number of mounting holes corresponding to the lenses for receiving the lenses. The substrate includes a positioning hole for mounting the mounting board. Cooperation of all the lenses can improve the image quality.

### FIELD OF THE PRESENT DISCLOSURE

The present disclosure relates to the field of image capturing, and more particularly to a camera module for capturing an image.

### DESCRIPTION OF RELATED ART

With development of technology, besides digital cameras, more and more portable electronic devices are equipped with image capturing functions. To achieve the image capturing function, a camera module is needed. Generally, a camera module includes a camera lens for collecting light reflected from an object, a sensor for receiving the light and converting the light to electrical signals, and processor for calculating the signals and outputting digital images.

A related imaging camera generally includes a lens holder and a plurality of lens units accommodated in the lens holder. For positioning the lens holder, the imaging camera further provides a housing for accommodating and fastening the lens holder. For most of the portable devices, such as mobile phones, only one camera module is provided for one device, on the front cover or the rear cover, which cannot provide excellent image quality.

Therefore, it is desired that an improved camera module can be developed to overcome the disadvantage mentioned above.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is an illustration of a camera module in accordance with an exemplary embodiment of the present invention.

FIG. 2 is a cross-sectional view of Part A in FIG. 1.

FIG. 3 is an exploded view of the camera module in FIG. 1.

FIG. 4 is an illustration of a camera in accordance with another exemplary embodiment of the present invention.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with is the figure and the embodiments. It should be understood the specific embodiments described hereby are only to explain the disclosure, not intended to limit the disclosure.

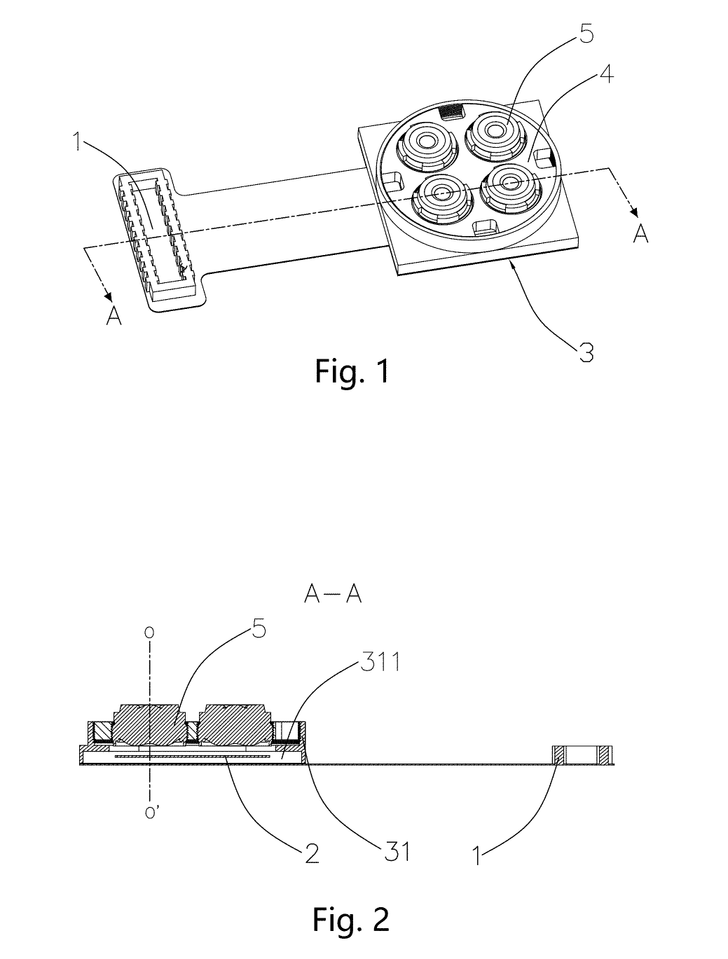

Referring to FIG. 1, a camera module in accordance with a first exemplary embodiment includes a circuit board 1, a substrate 3 mounted on the circuit board 1 and including a receiving area 311 (as shown in FIG. 2), a sensor 2 received in the receiving area 311 and electrically connected with the circuit board 1.

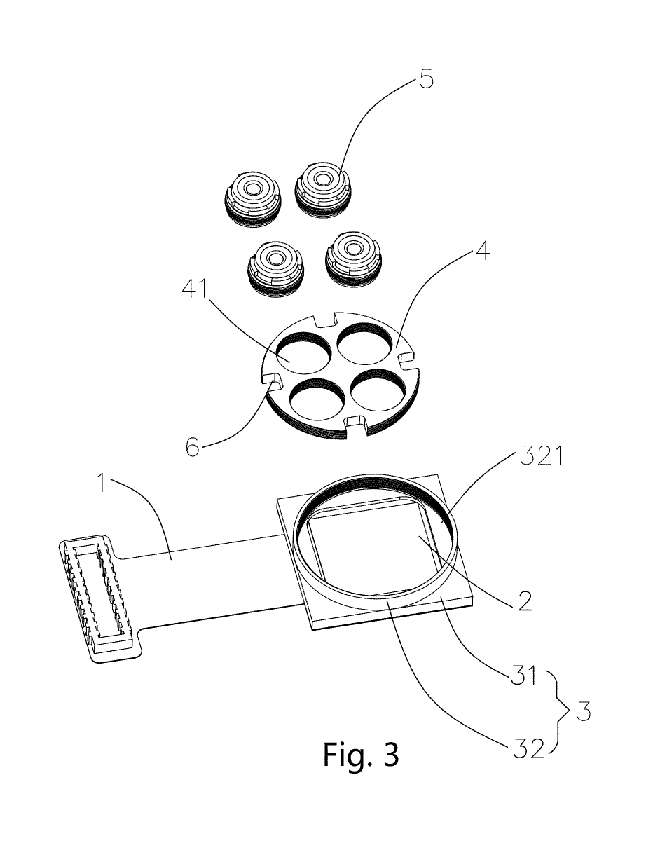

Referring to FIG. 3 together with FIGS. 1-2, the camera module further includes a plurality of lenses 5 and a mounting board 4 for carrying the plurality of lenses 5. The mounting board 4 includes a plurality of mounting holes 41, and the amount of the lenses 5 is corresponding to the mounting holes 41. In the embodiment, the amount of the lenses 5 and the amount of the mounting holes 41 are both four. The four mounting holes 41 are such arranged that the mounting holes 41 surrounds an axle center of the mounting board 4 and each mounting hole 41 keeps a distance to the axle center same to another mounting hole 41. Each of the lenses 5 is received in a corresponding mounting hole 41. In fact, the amount of the lenses and the mounting holes can be adjusted according to actual requirements. In the invention, no limitation to the amount of the lenses and the mounting holes is presented.

In addition, the substrate 3 further includes a positioning hole 321 for positioning the mounting board 4. Each of the lenses 5 includes an image side surface facing the sensor 2 when the mounting board 4 is positioned in the positioning hole 321. The positioning hole 321 is communicated with the receiving area 311.

When the camera module works, the incident light arrives at the sensor 2 through the four lenses 5 and the sensor 2 converts the light signals into electrical signals containing image information then transmits the electrical signals to a terminal. In the embodiment, the lenses 5 includes a wide-angle lens, a telephoto lens, a large depth-filed lens, and a fish-eye lens. The wide-angle lens has a relatively short focal length but meanwhile has a wide angle, which is beneficial for scenery photograph. The telephoto lens is beneficial for portrait. The large depth-field lens is beneficial for capturing clear distant view and close shot. The fish-eye lens has the greatest view-angle but will cause distortion. The terminal is capable of compounding the light from all the lenses and use all the advantages of the lenses to get high quality images.

In the embodiment, referring to FIG. 3, the substrate 3 includes a bottom board 31 and a frame 32 assembled with the bottom board 31. Referring back to FIG. 2, the receiving area 311 is formed in the bottom board 31, and the positioning hole 321 is formed in the frame 32. The sensor 2 is mounted on the circuit board 1, and the bottom board 31 is fixed to the circuit board 1. The frame 32 extends upwardly for providing a space for the mounting board 4 with four lenses 5.

Referring to FIG. 3, the mounting board 4 is provided with outer threads, and the positioning hole 321 is provided inner threads for cooperating with the mounting board 4, by which the mounting board 4 is positioned in the positioning hole 321. Meanwhile, the mounting board 4 is movable in the positioning hole 321 by the cooperation between the outer and inner threads along an axis of the positioning hole 321. The movement of the mounting board 4 will change the image distance of the lenses 5, i.e., the distance from the lenses to the sensor 2 for focusing.

In addition, the mounting board 4 is provided with four recesses 6 for assisting user to assemble the mounting board 4 into the positioning hole 321. Each of the mounting holes 41 is provided with inner threads, and each of the lenses 5 is provided with outer threads, by which the lenses 5 is mounted in the mounting holes 41. Further, the lenses 5 are movable in the mounting holes 41 to change the corresponding image distances of the lenses. Therefore, the image distances of the lenses could be adjusted by the movement of the mounting board 4, and also, the image distance of each lens could be adjusted separately by the movement of each lens.

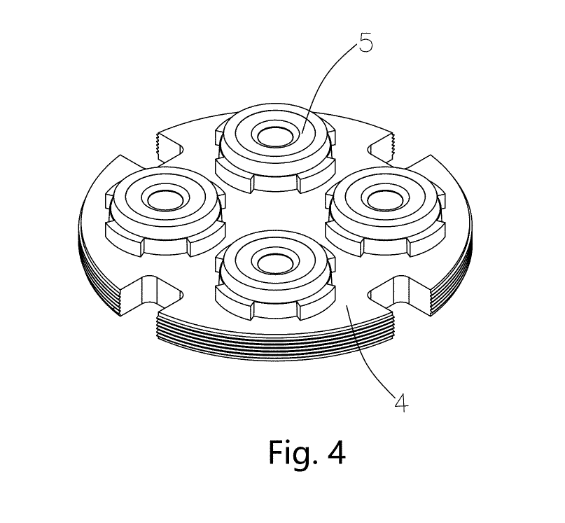

Referring to FIG. 4, a camera module in accordance with a second exemplary embodiment of the present invention is disclosed. In this embodiment, the four lenses 5 is fixed in the mounting holes, thus, the image distance of each lens cannot be adjusted separately, by which the focusing speed is improved.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A camera module, including:
a circuit board;
a sensor electrically connected to the circuit board;
a substrate mounted on the circuit board and including a receiving area for receiving the sensor;
a plurality of lenses;
a mounting board for carrying the lenses, the mounting board including a plurality of mounting holes corresponding to the lenses for receiving the lenses; wherein
the substrate includes a positioning hole for mounting the mounting board therein.

2. The camera module as described in claim 1, wherein the mounting board engages with the positioning hole by threads, and the mounting board is movable in the positioning hole along an optical axis of one of the lenses.

3. The camera module as described in claim 1, wherein the lenses are engaged with the mounting holes by threads, and the lenses are movable in the mounting holes along an optical axis of one of the lenses.

4. The camera module as described in claim 1, wherein the substrate includes a bottom board forming the receiving area and a frame including the positioning holes.

5. The camera module as described in claim 1, wherein the four mounting holes are such arranged that the mounting holes surrounds an axle center of the mounting board and each mounting hole keeps a distance to the axle center same to another mounting hole.

6. The camera module as described in claim 3, wherein the mounting board is provided with a plurality of recesses for mounting the mounting board.

7. The camera module as described in claim 1, wherein the lenses include different lenses or identical lenses.

8. The camera module as described in claim 7, wherein image surfaces of the lenses are coplanar with each other.

9. The camera module as described in claim 1, wherein image sides of the lenses all face the sensor when the mounting board is mounted in the positioning holes.
